(19) United States
(12) Patent Application Publication
(10) Pub. No.: US 2017/0194416 A1
(43) Pub. Date: Jul. 6, 2017

(54) ARRAY SUBSTRATE, METHOD FOR MANUFACTURING THE SAME AND DISPLAY DEVICE

(71) Applicant: BOE TECHNOLOGY GROUP CO., LTD., Beijing (CN)

(72) Inventors: Liqiang CHEN, Beijing (CN); Tao GAO, Beijing (CN); Jing GAO, Beijing (CN); Chen XU, Beijing (CN)

(73) Assignee: BOE TECHNOLOGY GROUP CO., LTD., Beijing (CN)

(21) Appl. No.: 15/321,151

(22) PCT Filed: Mar. 16, 2016
(86) PCT No.: PCT/CN2016/076490

§ 371 Date: Dec. 21, 2016

(30) Foreign Application Priority Data
Apr. 29, 2015 (CN) 201510212292.X

(51) Int. Cl. H01L 27/32; H01L 51/52; H01L 51/56

(52) U.S. Cl. CPC H01L 27/3281; H01L 27/3262; H01L 27/3246; H01L 27/3258; H01L 51/56; H01L 51/5209; H01L 51/5234; H01L 51/5225; H01L 27/3276; H01L 27/3288; H01L 2227/323

(57) ABSTRACT

The present disclosure relates to the field of display technology, and provides an array substrate, its manufacturing method and a display device. The array substrate includes a display region and a GOA circuit region arranged outside the display region. A PMOLED display array is formed at the GOA circuit region.

### CROSS-REFERENCE TO RELATED APPLICATIONS

The present application claims a priority of the Chinese patent application No. 201510212292.X filed on Apr. 29, 2015, which is incorporated herein by reference in its entirety.

### TECHNICAL FIELD

The present disclosure relates to the field of display technology, in particular to an array substrate, a method for manufacturing the same and a display device.

### BACKGROUND

Currently, a flat-panel display device mainly includes a liquid crystal display (LCD), a plasma display panel (PDP) and an organic light-emitting diode (OLED) display device. As compared with the LCD, the OLED display device has such advantages as low power consumption, low weight, small thickness and being foldable, so it may become a new, mainstream display device to replace the LCD. The OLED display device may include, in terms of a driving mode, an active matrix OLED (AMOLED) display device and a passive matrix OLED (PMOLED) display device. The AMOLED display device may be used to achieve large-size display at low power consumption and a high resolution, but its manufacture process is relatively complex and the thin film transistor (TFT) stability is highly required. The PMOLED display device is of a simple structure and its manufacture process is simple, but it is difficult to achieve the large-size display.

In order to improve the user experience, a narrow-bezel display device has currently attracted more and more attentions. Usually, for the existing narrow-bezel display device, a width of a sealant at a non-display region, a width of a gate on array (GOA, which refers to a technique where a gate driver circuit is integrated into an array substrate) circuit and a width of a bonding region may be reduced, and meanwhile a distance between an edge of a display panel and a casing of the display device may be reduced, so as to reduce a width of a bezel of the display device, thereby to provide the narrow-bezel display device. For the AMOLED display device using the GOA technique, it is able to reduce the width of the bonding region, but it is still necessary to provide some regions for wiring. Hence, for a GOA circuit, there are still some regions that cannot be used for displaying an image. Actually, it is difficult to reduce a size of the GOA circuit in terms of process and design, so it is merely able for the existing AMOLED display device to reduce the width of the bezel, i.e., it is impossible for it to achieve a display without bezel.

### SUMMARY

An object of the present disclosure is to provide an array substrate, its manufacturing method and a display device, so as to provide narrow-bezel, and even bezel-free display.

In one aspect, the present disclosure provides in some embodiments an array substrate including a display region and a GOA circuit region arranged outside the display region. A PMOLED display array is formed at the GOA circuit region.

Optionally, at the display region are formed a plurality of AMOLED display units arranged in a matrix form and a plurality of pixel TFTs each corresponding to one of the AMOLED display units. The PMOLED display array includes a plurality of PMOLED display units arranged in a matrix form and a plurality of gated TFTs each corresponding to one row of the PMOLED display units and one row of the pixel TFTs, and a gate electrode of each gated TFT is configured to receive a control signal identical to a gate electrode of each pixel TFT in the corresponding row of the pixel TFTs.

Optionally, each PMOLED display unit is of a size identical to the AMOLED display unit.

Optionally, a source electrode of the gated TFT is connected to a predetermined high level, and a drain electrode thereof is connected to a high-resistance element.

Optionally, the high-resistance element is a TFT, a gate electrode and a drain electrode of which are connected to each other, and a source electrode of which is connected to the drain electrode of the gated TFT.

In another aspect, the present disclosure provides in some embodiments a display device including the above-mentioned array substrate.

In yet another aspect, the present disclosure provides in some embodiments a method for manufacturing an array substrate. The array substrate includes a display region and a GOA circuit region arranged outside the display region. The method includes a step of forming a PMOLED display array at the GOA circuit region.

Optionally, the method further includes: forming at the display region a plurality of AMOLED display units arranged in a matrix form and a plurality of pixel TFTs each corresponding to one of the AMOLED display units; and forming at the GOA circuit region a plurality of PMOLED display units arranged in a matrix form and a plurality of gated TFTs each corresponding to one row of the PMOLED display units and one row of the pixel TFTs. A gate electrode of each gated TFT is configured to receive a control signal identical to a gate electrode of each pixel TFT in the corresponding row of the pixel TFTs.

Optionally, each PMOLED unit and each AMOLED display unit are formed in the same size.

Optionally, the method further includes: forming an active layer of each pixel TFT and an active layer of each gated TFT through a single patterning process; forming a gate insulation layer; forming a gate electrode of each pixel TFT and a gate electrode of each gated TFT through a single patterning process; forming an intermediate insulation layer; forming a source electrode and a drain electrode of each pixel TFT and a source electrode and a drain electrode of each gated TFT through a single patterning process; forming a planarization layer; forming an anode of each AMOLED display unit using a conductive layer and forming a strip-like row electrode using the conductive layer as an anode of each PMOLED display unit through a single patterning process; forming a pixel definition layer; forming a light-emitting layer of each AMOLED display unit and a light-emitting layer of each PMOLED display unit within a pixel region defined by the pixel definition layer; and forming a cathode of each AMOLED display unit using a transparent conductive layer and forming a strip-like column electrode using the transparent conductive layer as a cathode of each PMOLED display unit through a single patterning process.

In still yet another aspect, the present disclosure provides in some embodiments a method for manufacturing an array substrate, including steps of: providing a base substrate and forming a plurality of thin film transistors (TFTs) on the base substrate, the plurality of TFTs comprising a pixel TFT at an active matrix organic light-emitting diode (AMOLED) display region, a gated TFT for a row electrode of a passive matrix organic light-emitting diode (PMOLED), and a TFT at a gate on array (GOA) region; forming a planarization layer with a via-hole; forming an anode of an AMOLED and the row electrode of the PMOLED; and forming a pixel definition layer, an organic light-emitting layer, a cathode and a column electrode.

Optionally, the step of forming a plurality of TFTs includes: forming an active layer on the base substrate; forming a gate insulation layer and forming gate electrodes of the TFTs on the gate insulation layer; forming a pattern of an intermediate insulation layer with a via-hole; and forming patterns of source electrodes and drain electrodes of the TFTs.

Optionally, a source electrode of the gated TFT for the PMOLED is connected to a high-resistance element.

Optionally, in the case that the active layer of the TFT is formed with poly-silicon, the high-resistance element connected to the source electrode of the gated TFT is formed with poly-silicon simultaneously, and a resistance of the high-resistance element is adjustable through an injection process.

Optionally, the high-resistance element is a TFT, a gate electrode and a source electrode of which are connected to each other, and a source electrode of which is connected to the drain electrode of the gated TFT.

Optionally, a common electrode is formed through a same patterning process as forming the anode of the AMOLED and the row electrode of the PMOLED.

According to the embodiments of the present disclosure, the PMOLED display array may be formed at the GOA circuit region and connected to the AMOLED display units at the display region, so as to display an image collectively. In this way, it is able to display the image at the GOA circuit region too, thereby to provide a narrow-bezel or bezel-free display device.

### BRIEF DESCRIPTION OF THE DRAWINGS

FIG. 1 is a planar view of an array substrate according to at least one embodiment of the present disclosure;

FIG. 2 is an enlarged view of portion A of the array substrate in FIG. 1;

FIG. 3 is a sectional view of TFTs on the array substrate according to at least one embodiment of the present disclosure;

FIG. 4 is a schematic view showing the connection relationship between a gated TFT and a high-resistance element according to at least one embodiment of the present disclosure; and

FIG. 5 is a sectional view of the array substrate according to at least one embodiment of the present disclosure.

### DETAILED DESCRIPTION OF THE EMBODIMENTS

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

In order to make the objects, the technical solutions and the advantages of the present disclosure more apparent, the present disclosure will be described hereinafter in conjunction with the drawings and embodiments.

In the related art, it is impossible to provide a bezel-free AMOLED display device due to the existence of a GOA circuit region. An object of the present disclosure is to provide an array substrate, a method for manufacturing the same and a display device, so as to provide a narrow-bezel, or even bezel-free, display device.

The present disclosure provides in some embodiments an array substrate, which includes a display region and a GOA circuit region arranged outside the display region. A PMOLED display array is formed at the GOA circuit region.

For the AMOLED display, each AMOLED display unit needs to be driven by a corresponding TFT, but due to the wiring at the GOA circuit region of the array substrate, a TFT array cannot be formed at the GOA circuit region, so an AMOLED display array cannot be formed at the GOA circuit region. For the PMOLED display, PMOLED display units in each row are driven by a gated TFT. In the embodiments of the present disclosure, the PMOLED display array may be formed at the GOA circuit region and connected to the AMOLED display units at the display region, so as to display an image collectively. In this regard, it is able to display the image at the GOA circuit region too, thereby to provide a narrow-bezel or bezel-free display device.

Further, at the display region are formed a plurality of AMOLED display units arranged in a matrix form and a plurality of pixel TFTs each corresponding to one of the AMOLED display units. The PMOLED display array includes a plurality of PMOLED display units arranged in a matrix form and a plurality of gated TFTs each corresponding to one row of the PMOLED display units and one row of the pixel TFTs, and a gate electrode of each gated TFT is configured to receive a control signal identical to a gate electrode of each pixel TFT in the corresponding row of the pixel TFTs. In this way, the PMOLED display units and the AMOLED display units may cooperate with each other so as to display the image collectively.

In order to enable a brightness value of each PMOLED display unit to match that of the AMOLED display unit, optionally each PMOLED display unit is of a size identical to that of the AMOLED display unit.

Further, in order to apply a high level to a row electrode of the PMOLED display array after it has received a scanning signal and thereby to enable an OLED to emit light, a source electrode of each gated TFT is connected to a predetermined high level, and a drain electrode thereof is connected to a high-resistance element.

To be specific, the high-resistance element may be a TFT, a gate electrode and a drain electrode of which are connected to each other, and a source electrode of which is connected to the drain electrode of the gated TFT.

The present disclosure further provides in some embodiments a display device including the above-mentioned array substrate. The display device may be any product or member having a display function, such as a display panel, a television, a display, a digital photo frame, a mobile phone or a flat-panel computer.

The present disclosure further provides in some embodiments a method for manufacturing an array substrate. The array substrate includes a display region and a GOA circuit region arranged outside the display region. The method includes a step of forming a PMOLED display array at the GOA circuit region.

For the AMOLED display, each AMOLED display unit needs to be driven by a corresponding TFT, but due to the wiring at the GOA circuit region of the array substrate, a TFT array cannot be formed at the GOA circuit region, so an AMOLED display array cannot be formed at the GOA circuit region. For the PMOLED display, PMOLED display units in each row are driven by a gated TFT. In the embodiments of the present disclosure, the PMOLED display array may be formed at the GOA circuit region and connected to the AMOLED display units at the display region, so as to display an image collectively. In this regard, it is able to display the image at the GOA circuit region too, thereby to provide a narrow-bezel or bezel-free display device.

The method further includes: forming at the display region a plurality of AMOLED display units arranged in a matrix form and a plurality of pixel TFTs each corresponding to one of the AMOLED display units; and forming at the GOA circuit region a plurality of PMOLED display units arranged in a matrix form and a plurality of gated TFTs each corresponding to one row of the PMOLED display units and one row of the pixel TFTs. A gate electrode of each gated TFT is configured to receive a control signal identical to a gate electrode of each pixel TFT in the corresponding row of the pixel TFTs. In this way, the PMOLED display unit may cooperate with the AMOLED display unit, so as to display the image collectively.

Further, each PMOLED unit is of a size identical to that of the AMOLED display unit, so that a brightness value of each PMOLED unit may match that of the AMOLED display unit.

Further, the method may include steps of: forming an active layer of each pixel TFT and an active layer of each gated TFT through a single patterning process; forming a gate insulation layer; forming a gate electrode of each pixel TFT and a gate electrode of each gated TFT through a single patterning process; forming an intermediate insulation layer; forming a source electrode and a drain electrode of each pixel TFT and a source electrode and a drain electrode of each gated TFT through a single patterning process; forming a planarization layer; forming an anode of each AMOLED unit using a conductive layer and forming a strip-like row electrode using the conductive layer as an anode of each PMOLED display unit through a single patterning process; forming a pixel definition layer; forming a light-emitting layer of each AMOLED display unit and a light-emitting layer of each PMOLED display unit within a pixel region defined by the pixel definition layer; and forming a cathode of each AMOLED display unit using a transparent conductive layer and forming a strip-like column electrode using the transparent conductive layer as a cathode of each PMOLED display unit through a single patterning process.

The present disclosure will be described hereinafter in conjunction with the drawings and embodiments.

Depending on different driving modes, an OLED may include a PMOLED and an AMOLED. For a PMOLED display device, anodes and cathodes of PMOLEDs are arranged in a matrix form, so as to light up pixels in the matrix by a scanning way. Each pixel is operated in a short pulse mode and may emit light instantaneously at a large brightness value. The PMOLED display device is of a simple structure, so the production cost may be reduced.

A display region of the PMOLED display device may include N*M (N and M are each a natural number) display units arranged in a matrix form, and each display unit corresponds to one OLED. The cathodes of the N*M OLEDs form an entire planar electrode. For the AMOLED display, each AMOLED display unit needs to be driven by a corresponding TFT, but due to the wiring at the GOA circuit region of the array substrate, a TFT array cannot be formed at the GOA circuit region, so an AMOLED display array cannot be formed at the GOA circuit region. For the PMOLED display, PMOLED display units in each row are driven by a gated TFT, so fewer TFTs are required. In the embodiments of the present disclosure, the PMOLED display array may be formed at the GOA circuit region and connected to the AMOLED display units at the display region, so as to display an image collectively. In this regard, it is able to display the image at the GOA circuit region too, thereby to provide a narrow-bezel or bezel-free display device.

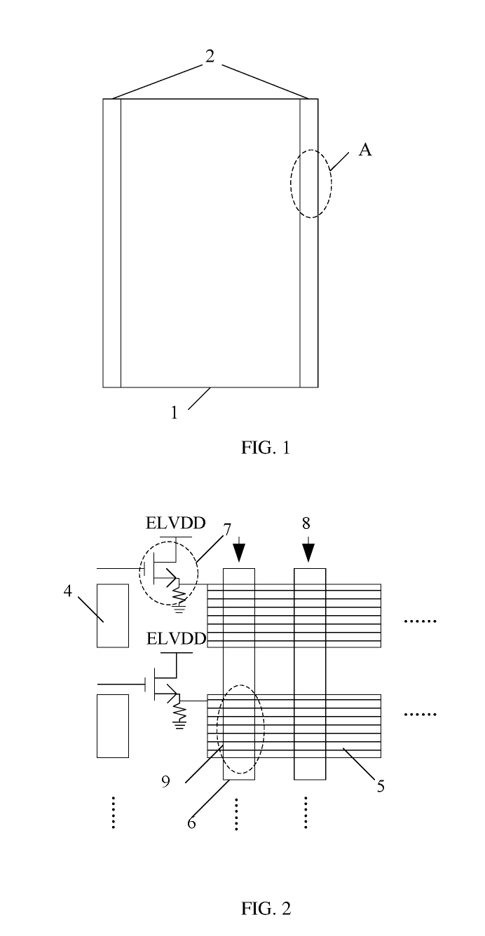

To be specific, as shown in FIGS. 1 and 2, the array substrate in the embodiments of the present disclosure includes an AMOLED display region 1 and a PMOLED display region 2 located arranged outside an outermost pixel 4 in the AMOLED display region. The PMOLED display array includes a plurality of strip-like PMOLED row electrodes 5 and a plurality of strip-like PMOLED column electrodes 6. During the operation of the PMOLED display array, each PMOLED row electrode 5 may be electrically connected to the corresponding gated TFT 7, and each PMOLED column electrode 6 may be driven by a constant current source 8. A plurality of pixels 9 at the PMOLED display region is defined by PMOLED row electrodes 5 and the PMOLED column electrodes 6.

The method for manufacturing the array substrate may include the following steps.

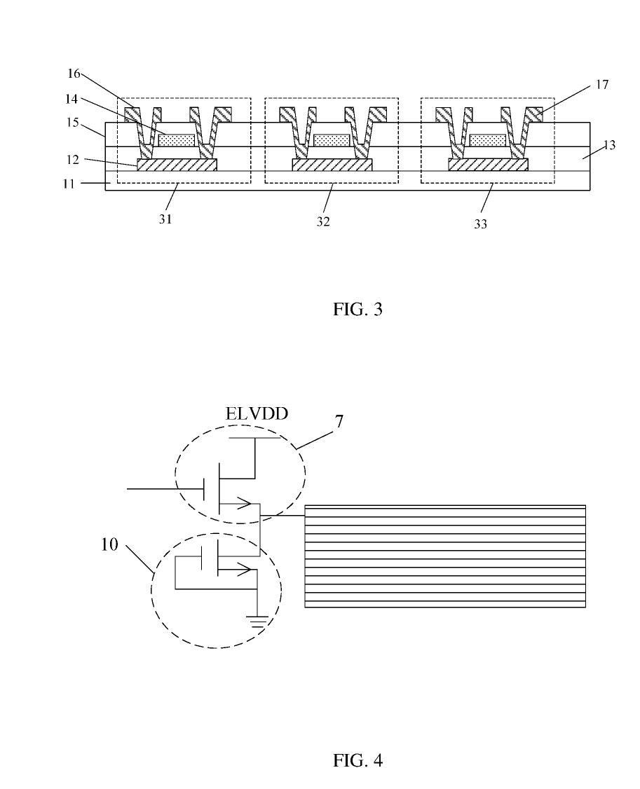

Step 1: providing a base substrate 11, and forming TFTs on the base substrate 11. As shown in FIG. 3, the TFTs formed on the base substrate 11 include a pixel TFT 31 at the AMOLED display region and a gated TFT 32 for the PMOLED row electrode and a TFT 33 at the GOA region.

The step of forming the TFTs may include the following steps.

Step 11: providing the base substrate 11 and forming an active layer 12 on the base substrate 11. The base substrate 11 may be a quartz or glass substrate, and for example, it may be a glass substrate having a thickness of 0.4 to 0.7 mm. To be specific, the base substrate 11 may be cleaned, and then an amorphous silicon (a-Si:H) layer having a thickness of 400 to 600 Å may be deposited on the cleaned base substrate 11. Next, the a-Si layer may be subjected to excimer laser annealing to acquire a poly-silicon layer. Then, a photoresist may be applied onto the poly-silicon layer, so as to form a pattern of the active layer 12 through exposing, developing and dry-etching.

Step 12: forming a gate insulation layer 13 and forming a gate electrode 14 on the gate insulation layer 13. To be specific, the gate insulation layer 13 having a thickness of about 1000 to 6000 Å may be deposited onto the base substrate 11 obtained after Step 11 through plasma enhanced chemical vapor deposition (PECVD). The gate insulation layer may be made of an oxide, a nitride or an oxynitride, and it may be of a single-layered or multi-layered layer. For example, the gate insulation layer may be made of SiNₓ, SiOₓ or Si(ON)ₓ. For another example, the gate insulation layer may consist of a SiNₓ layer having a thickness of 500 Å and a SiO₂ layer having a thickness of 1000 Å.

Then, a gate metal layer having a thickness of 2500 Å to 16000 Å may be deposited onto the gate insulation layer 13 through sputtering or thermal evaporation. The gate metal layer may be made of copper (Cu), aluminum (Al), silver (Ag), molybdenum (Mo), chromium (Cr), neodymium (Nd), nickel (Ni), manganese (Mn), titanium (Ti), tantalum (Ta) or tungsten (W), or an alloy thereof, and it may be of a single-layered structure, or a multi-layered structure such as Cu/Mo, Ti/Cu/Ti or Mo/Al/Mo. Next, a photoresist may be applied onto the gate metal layer, and then exposed with a mask plate, so as to form a photoresist reserved region corresponding to a region where patterns of a gate line and the gate electrode 14 are located, and a photoresist unreserved region corresponding to the other region. Next, a developing process may be performed, so as to remove the photoresist at the photoresist unreserved region and maintain the photoresist at the photoresist reserved region. Then, a gate metal film at the photoresist unreserved region may be etched off through an etching process, and the remaining photoresist may be removed, so as to form the patterns of the gate line and the gate electrode 14.

Step 13: forming a pattern of an intermediate insulation layer 15 with via-holes. To be specific, an intermediate insulation film having a thickness of 400 to 5000 Å may be deposited onto the base substrate 11 obtained after Step 12 through magnetron sputtering, thermal evaporation, PECVD or any other film-forming method. The intermediate insulation film may be made of an oxide, a nitride or an oxynitride, e.g., it may be made of SiNₓ, SiOₓ or Si(ON)ₓ. The intermediate insulation film may be of a single-layered structure, or a double-layered structure consisting of a SiNₓ layer and a SiOₓ layer. For example, the intermediate insulation film may consist of a SiNₓ layer having a thickness of 3000 Å and a SiO₂ layer having a thickness of 2000 Å.

Next, a photoresist may be applied onto the intermediate insulation film, and then exposed with a mask plate, so as to form a photoresist reserved region corresponding to a region where a pattern of the intermediate insulation layer 15 is located and a photoresist unreserved region corresponding to the other region. Then, a developing process may be performed, so as to remove the photoresist at the photoresist unreserved region and maintain the photoresist at the photoresist reserved region. Then, the intermediate insulation film at the photoresist unreserved region may be etched off through an etching process and the remaining photoresist may be removed, so as to form the pattern of the intermediate layer 15 with the via-holes.

Step 14: forming patterns of a source electrode 16 and a drain electrode 17. To be specific, a source-drain metal layer having a thickness of about 2000 to 6000 Å may be deposited onto the base substrate 11 obtained after Step 13 through magnetron sputtering, thermal evaporation or any other film-forming method. The source-drain metal layer may be made of Cu, Al, Ag, Mo, Cr, Nd, Ni, Mn, Ti, Ta or W, or an alloy thereof, and it may be of a single-layered structure, or a multi-layered structure such as Cu/Mo, Ti/Cu/Ti or Mo/Al/Mo. For example, the source-drain metal layer may consist of a Ti layer having a thickness of 500 Å, an Al layer having thickness of 2000 Å and a Ti layer having a thickness of 500 Å.

Next, a photoresist may be applied onto the source-drain metal layer, and then exposed with a mask plate, so as to form a photoresist reserved region corresponding to a region where patterns of the source electrode 16, the drain electrode 17 and a data line are located, and a photoresist unreserved region corresponding to the other regions. Then, a developing process may be performed, so as to remove the photoresist at the photoresist unreserved region and maintain the thickness of photoresist at the photoresist reserved region unchanged. Next, the source-drain metal layer at the photoresist unreserved region may be removed through an etching process, and the remaining photoresist may be removed, so as to form the source electrode 16, the drain electrode 17 and the data line.

The structure in FIG. 3 may be formed through the above-mentioned Steps 11 to 14. For the PMOLED, the source electrode of the gated TFT needs to be connected to a large resistor, so that a high voltage ELVDD may be applied to the row electrode in the case that the gated TFT is turned on. In the case that the active layer of the TFT is formed by poly-silicon, the high-resistance element connected to the source electrode of the gated TFT may be formed by poly-silicon too, and a resistance of the high-resistance element may be adjustable through an injection process. In the case that the active layer of the TFT is not formed by poly-silicon, a TFT10 in FIG. 4 may serve as the high-resistance element. A gate electrode and a source electrode of the TFT 10 may be connected together, and a source electrode thereof may be connected to the drain electrode of the gated TFT.

Subsequent to the formation of the TFTs on the base substrate 11, the method may further include the following steps.

Step 2: forming a planarization layer 18 with via-holes. To be specific, a layer of resin material may be applied onto the base substrate 11 obtained after Step 14. The resin material may be photosensitive or non-photosensitive resin. Next, the resin layer may be exposed with a mask plate, and then developed or etched through a dry-etching process, so as to form a pattern of the planarization layer 18 with the via-holes.

Step 3: forming an anode 19 of each AMOLED and a row electrode 20 of each PMOLED. To be specific, a conductive layer having a thickness of about 2000 to 6000 Å may be deposited onto the base substrate obtained after Step 2 through magnetron sputtering, thermal evaporation or any other film-forming method. The conductive layer may be made of indium tin oxide (ITO), indium zinc oxide (IZO) or Ag. The conductive layer may be of a single-layered or multi-layered structure, e.g., it may consist of an ITO layer having a thickness of 100 Å, an Ag layer having a thickness of 1000 Å and an ITO layer having thickness of 100 Å.

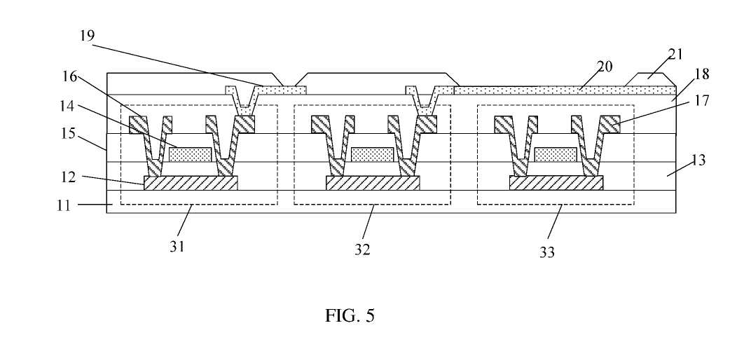

Next, a photoresist may be applied onto the conductive layer, and then exposed with a mask plate, so as to form a photoresist reserved region corresponding to a region where patterns of the anode 19 and the row electrode 20 are located, and a photoresist unreserved region corresponding to the other regions. Next, a developing process may be performed, so as to remove the photoresist at the photoresist unreserved region and maintain the thickness of the photoresist at the photoresist reserved region unchanged. Then, the conductive layer at the photoresist unreserved region may be etched off through an etching process, and the remaining photoresist may be removed, so as to form the anode 19 and the strip-like row electrode 20. The anode 19 may be connected to a drain electrode 17 of the TFT 31 through one via-hole in the planarization layer, and the strip-like row electrode 20 may be connected to a drain electrode 17 of the gated TFT 32 through another via-hole in the planarization layer. As shown in FIG. 5, the strip-like row electrode 20 covers the GOA circuit region and serves as the anode of the PMOLED. Upon the receipt of a scanning signal, the row electrode 20 is connected to a high level so as to enable the OLED to emit light, and in the case that the row electrode is not electrically connected to the gated electrode, it is grounded.

Further, a common electrode may be formed through a single patterning process while forming the anode and the row electrode.

Step 4: forming a pixel definition layer, an organic light-emitting layer, a cathode and a column electrode. To be specific, a polyimide (PI) layer may be applied onto the base substrate 11 obtained after Step 3, and then exposed and developed to form the pixel definition layers 21 as shown in FIG. 5. Next, the organic light-emitting layer may be formed on the anode 19 and the row electrode 20 between the adjacent pixel definition layers 21. Usually, the organic light-emitting layer includes a hole injection layer, a hole transmission layer, a light-emitting layer, a hole blocking layer, an electron blocking layer, an electron transmission layer and an electron injection layer.

Next, a transparent conductive layer having a thickness of about 2000 to 6000 Å may be deposited on the base substrate 11 with the organic light-emitting layer through magnetron sputtering, thermal evaporation or any other film-forming method. The transparent conductive layer may be made of ITO, IZO or Ag, and it may be of a single-layered or multi-layered structure. Next, a photoresist may be applied onto the transparent conductive layer, and then exposed with a mask plate, so as to form a photoresist reserved region corresponding to a region where patterns of the cathode and the column electrode are located, and a photoresist unreserved region corresponding to the other regions. Next, a developing process may be performed, so as to remove the photoresist at the photoresist unreserved region and maintain the thickness of the photoresist at the photoresist reserved region unchanged. Then, the transparent conductive layer at the photoresist unreserved region may be etched off through an etching process, and the remaining photoresist may be removed, so as to form the cathode and the column electrode, thereby to form the array substrate in the embodiments of the present disclosure. At the AMOLED display region, the cathodes are formed in one piece and connected to the common electrode, while at the PMOLED display region, the cathodes of the PMOLED are strip-like column electrodes, and a driving signal is applied by a constant current source to the cathodes.

During the formation of the pixel definition layer, a PMOLED pixel region needs to be of a size identical to an AMOLED pixel region, or the size of the PMOLED pixel region may be adjusted in accordance with a brightness value at the PMOLED display region so as to match a brightness value at the AMOLED display region. A light intensity of each PMOLED pixel may be controlled by controlling a Data signal applied to the column electrode. Each PMOLED is driven by current, and in order to enable the PMOLED to cooperate with the AMOLED in a better manner, the Data signal may be amplified or current conversion may be performed, or the PMOLED may be driven separately so as to process separately a signal for a peripheral portion of an image. In this way, it is able to enable the PMOLED and the AMOLED to display the image synchronously.

The PMOLED display array at the GOA circuit region may be configured to display an entire image together with the AMOLED display units at the display region, or display various functional keys. For example, in the case that the array substrate is applied to a mobile phone, the functional keys may be provided at one side a display screen and displayed through the PMOLED display array, so as to facilitate the operation. In the case that the PMOLED display array is merely used to display the functional keys, it is unnecessary to provide a high resolution, so each PMOLED display unit may be of a larger size, so as to reduce its resistance and facilitate the manufacture thereof. At this time, the row electrodes of the PMOLED display array may be connected to the gated TFTs in an interlaced manner, i.e., the row electrodes in odd-numbered rows may be connected to the gated TFTs for displaying an image, while the row electrodes in even-numbered rows may not be connected to the gated TFTs. Correspondingly, a refresh rate needs to be adjusted, so as to reduce the occurrence of such phenomenon as flickering.

The above are merely the preferred embodiments of the present disclosure. Obviously, a person skilled in the art may make further modifications and improvements without departing from the spirit of the present disclosure, and these modifications and improvements shall also fall within the scope of the present disclosure.

1. An array substrate, comprising a display region and a gate on array (GOA) circuit region arranged outside the display region, wherein a passive matrix organic light-emitting diode (PMOLED) display array is formed at the GOA circuit region.

2. The array substrate according to claim 1, wherein at the display region are formed a plurality of active matrix organic light-emitting diode (AMOLED) display units arranged in a matrix form and a plurality of pixel thin film transistors (TFTs) each corresponding to one of the AMOLED display units; and
the PMOLED display array comprises a plurality of PMOLED display units arranged in a matrix form and a plurality of gated TFTs each corresponding to one row of the PMOLED display units and one row of the pixel TFTs, and a gate electrode of each gated TFT is configured to receive a control signal identical to a gate electrode of each pixel TFT in the corresponding row of the pixel TFTs.

3. The array substrate according to claim 2, wherein each PMOLED display unit is of a size identical to the AMOLED display unit.

4. The array substrate according to claim 2, wherein a source electrode of the gated TFT is connected to a predetermined high level, and a drain electrode of the gated TFT is connected to a high-resistance element.

5. The array substrate according to claim 4, wherein the high-resistance element is a TFT, a gate electrode and a drain electrode of the TFT are connected to each other, and a source electrode of the TFT is connected to the drain electrode of the gated TFT.

6. A display device, comprising the array substrate according to claim 1.

7. A method form manufacturing an array substrate, the array substrate comprising a display region and a gate on array (GOA) circuit region arranged outside the display region, the method comprising a step of forming a passive matrix organic light-emitting diode (PMOLED) display array at the GOA circuit region.

8. The method according to claim 7, further comprising
forming at the display region a plurality of active matrix organic light-emitting diode (AMOLED) display units arranged in a matrix form and a plurality of pixel thin film transistors (TFTs) each corresponding to one of the AMOLED display units; and
forming at the GOA circuit region a plurality of PMOLED display units arranged in a matrix form and a plurality of gated TFTs each corresponding to one row of the PMOLED display units and one row of the pixel TFTs,
wherein a gate electrode of each gated TFT is configured to receive a control signal identical to a gate electrode of each pixel TFT in the corresponding row of the pixel TFTs.

9. The method according to claim 8, wherein each PMOLED unit and each AMOLED display unit are formed in the same size.

10. The method according to claim 8, comprising steps of:
forming an active layer of each pixel TFT and an active layer of each gated TFT through a single patterning process;
forming a gate insulation layer;
forming a gate electrode of each pixel TFT and a gate electrode of each gated TFT through a single patterning process;
forming an intermediate insulation layer;
forming a source electrode and a drain electrode of each pixel TFT and a source electrode and a drain electrode of each gated TFT through a single patterning process;
forming a planarization layer;
forming an anode of each AMOLED display unit using a conductive layer and forming a strip-like row electrode using the conductive layer as an anode of each PMOLED display unit through a single patterning process;
forming a pixel definition layer;
forming a light-emitting layer of each AMOLED display unit and a light-emitting layer of each PMOLED display unit within a pixel region defined by the pixel definition layer; and
forming a cathode of each AMOLED display unit using a transparent conductive layer and forming a strip-like column electrode using the transparent conductive layer as a cathode of each PMOLED display unit through a single patterning process.

11. A method for manufacturing an array substrate, comprising steps of:
providing a base substrate and forming a plurality of thin film transistors (TFTs) on the base substrate, the plurality of TFTs comprising a pixel TFT at an active matrix organic light-emitting diode (AMOLED) display region, a gated TFT for a row electrode of a passive matrix organic light-emitting diode (PMOLED), and a TFT at a gate on array (GOA) region;
forming a planarization layer with a via-hole;
forming an anode of an AMOLED and the row electrode of the PMOLED; and
forming a pixel definition layer, an organic light-emitting layer, a cathode and a column electrode.

12. The method according to claim 11, wherein the step of forming a plurality of TFTs comprises:
forming an active layer on the base substrate;
forming a gate insulation layer and forming gate electrodes of the TFTs on the gate insulation layer;
forming a pattern of an intermediate insulation layer with a via-hole; and
forming patterns of source electrodes and drain electrodes of the TFTs.

13. The method according to claim 12, wherein a source electrode of the gated TFT for the PMOLED is connected to a high-resistance element.

14. The method according to claim 13, wherein in the case that the active layer of the TFT is formed with poly-silicon, the high-resistance element connected to the source electrode of the gated TFT is formed with poly-silicon simultaneously, and a resistance of the high-resistance element is adjustable through an injection process.

15. The method according to claim 13, wherein the high-resistance element is a TFT, a gate electrode and a source electrode of the TFT are connected to each other, and a source electrode of the TFT is connected to the drain electrode of the gated TFT.

16. The method according to claim 11, wherein a common electrode is formed through a same patterning process as forming the anode of the AMOLED and the row electrode of the PMOLED.
